(19) United States
(12) Patent Application Publication
(10) Pub. No.: US 2026/0026226 A1
(43) Pub. Date: Jan. 22, 2026

(54) DISPLAY DEVICE, OPTICAL DEVICE, AND ELECTRONIC DEVICE

(71) Applicant: Samsung Display Co., LTD., Yongin-si (KR)

(72) Inventors: Dae Ho LEE, Yongin-si (KR); Young Min KIM, Yongin-si (KR)

(21) Appl. No.: 19/226,547

(22) Filed: Jun. 3, 2025

(30) Foreign Application Priority Data
Jul. 17, 2024 (KR) 10-2024-0094677
Jan. 23, 2025 (KR) 10-2025-0010430

(51) Int. Cl. H10K 59/38; H10K 59/65; H10K 77/10; H10K 102/00

(52) U.S. Cl. CPC H10K 59/38; H10K 59/65; H10K 77/111; H10K 2102/311

(57) ABSTRACT

The present disclosure relates to a display device, an optical device, and an electronic device capable of sensing an external object. The display device includes: a substrate; and a first pixel, a second pixel, and a light sensor module disposed on the substrate, wherein the first pixel includes a first light emitting element and a first color filter disposed on the first light emitting element, and the second pixel includes a second light emitting element, a second color filter disposed on the second light emitting element, and an invisible light filter disposed on the second color filter.

This application claims priority to Korean Patent Application No. 10-2024-0094677, filed on Jul. 17, 2024, and Korean Patent Application No. 10-2025-0010430, filed on Jan. 23, 2025, and all the benefits accruing therefrom under 35 U.S.C. § 119, the contents of which in their entirety are herein incorporated by reference.

### BACKGROUND

### 1. Field

The present disclosure relates to a display device, and more particularly, to a display device, an optical device, and an electronic device capable of sensing an external object.

### 2. Description of the Related Art

Organic light emitting diode displays have self-luminous properties and may be implemented without separate light sources unlike liquid crystal displays, and thus organic light emitting diode displays may have a reduced thickness and weight. Organic light emitting diode displays have attracted attention as next-generation display devices for televisions (TVs), monitors, and portable electronic devices because they exhibit high-quality characteristics such as low power consumption, high luminance, and a high response speed.

### SUMMARY

Aspects of the present disclosure provide a display device, an optical device, and an electronic device capable of sensing an external object.

According to an aspect of the present disclosure, a display device includes: a substrate; and a first pixel, a second pixel, and a light sensor module disposed on the substrate, wherein the first pixel includes a first light emitting element and a first color filter disposed on the first light emitting element, and the second pixel includes a second light emitting element, a second color filter disposed on the second light emitting element, and an invisible light filter disposed on the second color filter.

According to another aspect of the present disclosure, an optical device includes: a display device; and an optical path conversion member disposed on the display device, wherein the display device includes: a substrate; and a first pixel, a second pixel, and a light sensor module disposed on the substrate, the first pixel includes a first light emitting element and a first color filter disposed on the first light emitting element, and the second pixel includes a second light emitting element, a second color filter disposed on the second light emitting element, and an invisible light filter disposed on the second color filter.

According to still another aspect of the present disclosure, an optical device includes a display device providing a display screen, wherein the display device includes: a substrate; and a first pixel, a second pixel, and a light sensor module disposed on the substrate, the first pixel includes a first light emitting element and a first color filter disposed on the first light emitting element, and the second pixel includes a second light emitting element, a second color filter disposed on the second light emitting element, and an invisible light filter disposed on the second color filter.

Detailed contents of other embodiments are described in a detailed description and are illustrated in the drawings.

A display device, an optical device, and an electronic device according to an embodiment may sense an external object through pixels and a light sensor module. Accordingly, the display device, the optical device, and the electronic device may track a user's sight line.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a cross-sectional view illustrating the display device according to an embodiment;

FIG. 3 is a plan view illustrating a display unit of the display device according to an embodiment;

FIG. 4 is a block diagram illustrating a display panel and a display driver according to an embodiment;

FIG. 5 is a cross-sectional view of the display device according to an embodiment;

FIG. 6 is a cross-sectional view of a display device according to another embodiment;

FIG. 7 is a cross-sectional view of a display device according to another embodiment;

FIG. 8 is a cross-sectional view of a display device according to another embodiment;

FIG. 9 is a cross-sectional view of a display device according to another

embodiment.

FIG. 10 is a cross-sectional view of a display device according to another embodiment;

FIG. 11 is a cross-sectional view of a display device according to another embodiment;

FIG. 12 is a cross-sectional view of a display device according to another embodiment;

FIG. 13 is a block diagram of an electronic device according to an embodiment;

FIGS. 14 to 16 are schematic views of electronic devices according to various embodiments;

FIG. 17 is a perspective view illustrating a head mounted display device according to an embodiment;

FIG. 18 is an exploded perspective view illustrating an example of the head mounted display device of FIG. 17; and

FIG. 19 is a perspective view illustrating a head mounted display device according to another embodiment.

### DETAILED DESCRIPTION

Embodiments supported by the present disclosure will now be described more fully hereinafter with reference to the accompanying drawings, in which example embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, and the like may be used herein to describe various elements, these elements, should not be limited by these terms. These terms may be used to distinguish one element from another element. Thus, a first element discussed below may be termed a second element without departing from teachings of one or more embodiments. The description of an element as a “first” element is not limited to requiring or implying the presence of a second element or other elements. The terms “first”, “second”, and the like may also be used herein to differentiate different categories or sets of elements. For conciseness, the terms “first”, “second”, and the like may represent “first-category (or first-set)”, “second-category (or second-set)”, and the like, respectively.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

Features of various embodiments of the present disclosure may be combined partially or totally. As will be clearly appreciated by those skilled in the art, technically various interactions and operations are possible. Various embodiments can be practiced individually or in combination.

Hereinafter, specific example embodiments will be described with reference to the accompanying drawings.

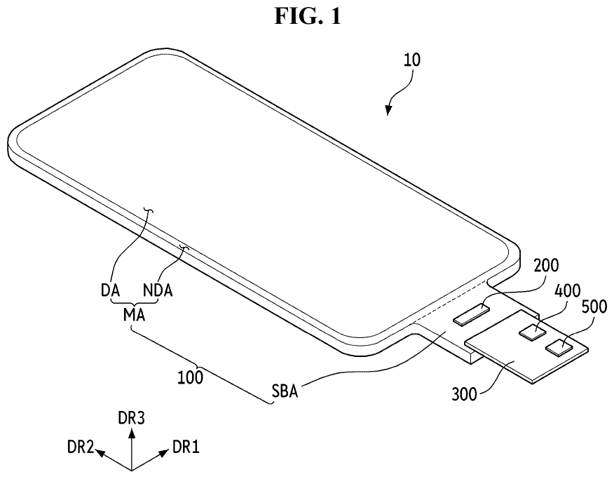

FIG. 1 is a perspective view illustrating a display device according to an embodiment.

Referring to FIG. 1, a display device 10 may be applied to portable electronic devices such as, for example, mobile phones, smartphones, tablet personal computers (PCs), mobile communication terminals, electronic notebooks, electronic books, portable multimedia players (PMPs), navigation devices, and ultra mobile PCs (UMPCs). As an example, the display device 10 may be applied as a display unit of televisions, laptop computers, monitors, billboards, or the Internet of Things (IOTs). As another example, the display device 10 may be applied to wearable devices such as, for example, smart watches, watch phones, glasses-type displays, and head mounted displays (HMDs).

The display device 10 may have a shape similar to a rectangular shape in a plan view. For example, the display device 10 may have a shape similar to a rectangular shape, in a plan view, having short sides in a first direction DR1 and long sides in a second direction DR2. A corner where the short side in the first direction DR1 and the long side in the second direction DR2 meet may be rounded with a selected curvature or right-angled. The shape of the display device 10 in a plan view is not limited to the rectangular shape, and may be a shape similar to other polygonal shapes, a circular shape, or an elliptical shape.

The display device 10 may include a display panel 100, a display driver 200, a circuit board 300, a touch driver 400, and a power supply unit 500.

The display panel 100 may include a main area MA and a sub-area SBA.

The main area MA may include a display area DA including pixels displaying an image and a non-display area NDA disposed around the display area DA. The display area DA may emit light from a plurality of emission areas or a plurality of opening areas. For example, the display panel 100 may include pixel circuits including switching elements, a pixel defining film defining the emission areas or the opening areas, and self-light emitting elements.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

The non-display area NDA may be an area outside the display area DA. The non-display area NDA may be defined as an edge area of the main area MA of the display panel 100. The non-display area NDA may include a gate driver (not illustrated) supplying gate signals to gate lines and fan-out lines (not illustrated) connecting the display driver 200 and the display area DA to each other.

The sub-area SBA may extend from one side of the main area MA. The sub-area SBA may include a flexible material that may be bent, folded, and rolled. In an example in which the sub-area SBA is bent, the sub-area SBA may overlap the main area MA in a thickness direction (e.g., a third direction DR3). The sub-area SBA may include the display driver 200 and pad portions connected to the circuit board 300. Alternatively, the sub-area SBA may be omitted, and the display driver 200 and the pad portions may be disposed in the non-display area NDA.

The display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be disposed in the sub-area SBA, and may overlap the main area MA in the thickness direction (third direction DR3) by bending of the sub-area SBA. As another example, the display driver 200 may be mounted on the circuit board 300.

The circuit board 300 may be attached onto the pad portions of the display panel 100 using an anisotropic conductive film (ACF). Lead lines of the circuit board 300 may be electrically connected to the pad portions of the display panel 100. The circuit board 300 may be a flexible printed circuit board, a printed circuit board, or a flexible film such as, for example, a chip on film.

The touch driver 400 may be mounted on the circuit board 300. The touch driver 400 may be electrically connected to a touch sensing unit of the display panel 100. The touch driver 400 may supply touch driving signals to a plurality of touch electrodes of the touch sensing unit and sense change amounts in capacitance between the plurality of touch electrodes. For example, the touch driving signal may be a pulse signal having a selected frequency. The touch driver 400 may decide whether or not an input has occurred and calculate input coordinates, based on the change amounts in capacitance between the plurality of touch electrodes. The touch driver 400 may be formed as an integrated circuit (IC).

The power supply unit 500 may be disposed on the circuit board 300 and may supply source voltages to the display driver 200 and the display panel 100. The power supply unit 500 may generate a driving voltage and supply the driving voltage to a driving voltage line VDL, may generate initialization voltages (e.g., a first initialization voltage and a second initialization voltage) and supply the initialization voltages to initialization voltage lines (e.g., a first initialization voltage line VIL1 and a second initialization voltage line VIL2), and may generate a common voltage and supply the common voltage to a common electrode (e.g., a cathode electrode) common to light emitting elements of a plurality of pixels. For example, the driving voltage may be a high-potential voltage for driving the light emitting element, and the common voltage may be a low-potential voltage for driving the light emitting element.

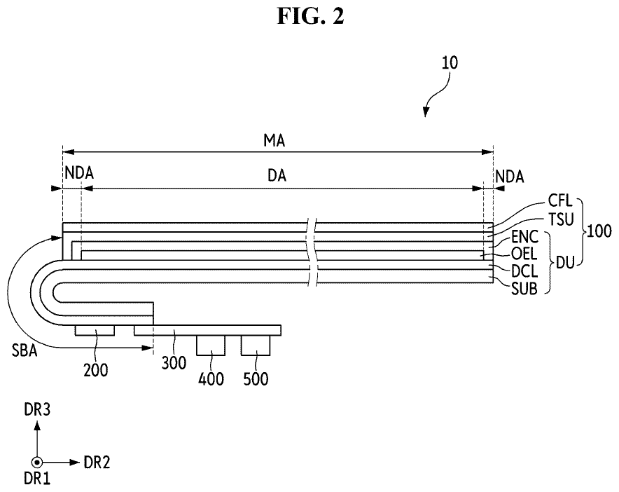

FIG. 2 is a cross-sectional view illustrating the display device according to an embodiment.

Referring to FIG. 2, the display panel 100 may include a display unit DU, a touch sensing unit TSU, and a color filter layer CFL. The display unit DU may include a substrate SUB, a driving circuit layer DCL, an optical element layer OEL, and an encapsulation layer ENC.

The driving circuit layer DCL may be disposed on the substrate SUB. The driving circuit layer DCL may include a plurality of transistors (e.g., thin film transistors) constituting pixel circuits of the pixels. The driving circuit layer DCL may further include gate lines, data lines, power lines, gate control lines, fan-out lines connecting the display driver 200 and the data lines to each other, and lead lines connecting the display driver 200 and the pad portions to each other.

The driving circuit layer DCL may be disposed in the display area DA, the non-display area NDA, and the sub-area SBA. The transistors of each of the pixels, the gate lines, the data lines, and the power lines of the driving circuit layer DCL may be disposed in the display area DA. The gate control lines and the fan-out lines of the driving circuit layer DCL may be disposed in the non-display area NDA. The lead lines of the driving circuit layer DCL may be disposed in the sub-area SBA.

The optical element layer OEL may be disposed on the driving circuit layer DCL. The optical element layer OEL may include a plurality of light emitting elements in which a pixel electrode (e.g., an anode electrode), a light emitting layer, and a common electrode (e.g., a cathode electrode) are sequentially stacked to emit light and a bank defining the pixels. The plurality of light emitting elements of the optical element layer OEL may be disposed in the display area DA.

The light emitting layer may be an organic light emitting layer including an organic material. The light emitting layer may include a hole transporting layer, an organic light emitting layer, and an electron transporting layer. In an example in which the pixel electrode receives a selected voltage through the transistor of the driving circuit layer DCL and the common electrode receives a cathode voltage, holes and electrons may move to the organic light emitting layer through the hole transporting layer and the electron transporting layer, respectively, and may be combined with each other in the organic light emitting layer to emit light.

As another example, the plurality of light emitting elements may include quantum dot light emitting diodes each including a quantum dot light emitting layer, inorganic light emitting diodes each including an inorganic semiconductor, or micro light emitting diodes.

The encapsulation layer ENC may cover an upper surface and side surfaces of the optical element layer OEL, and may protect the optical element layer OEL. The encapsulation layer ENC may include at least one inorganic film and at least one organic film for encapsulating the optical element layer OEL.

The touch sensing unit TSU may be disposed on the encapsulation layer ENC. The touch sensing unit TSU may include a plurality of touch electrodes for sensing a user's touch in a capacitance manner and touch lines connecting the plurality of touch electrodes and the touch driver 400 to each other. For example, the touch sensing unit TSU may sense the user's touch in a mutual capacitance manner or a self-capacitance manner.

As another example, the touch sensing unit TSU may be disposed on a separate substrate disposed on the display unit DU. In this case, the substrate supporting the touch sensing unit TSU may be a base member encapsulating the display unit DU.

The plurality of touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include a plurality of color filters respectively corresponding to the plurality of emission areas. Each of the color filters may selectively transmit light of a specific wavelength and block or absorb light of other wavelengths. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the touch sensing unit TSU, the display device 10 may be implemented without a separate substrate for the color filter layer CFL. Accordingly, a thickness of the display device 10 may be relatively reduced.

The sub-area SBA of the display panel 100 may extend from one side of the main area MA. The sub-area SBA may include a flexible material that may be bent, folded, and rolled. In an example in which the sub-area SBA is bent, the sub-area SBA may overlap the main area MA in the thickness direction (third direction DR3). The sub-area SBA may include the display driver 200 and the pad portions connected to the circuit board 300.

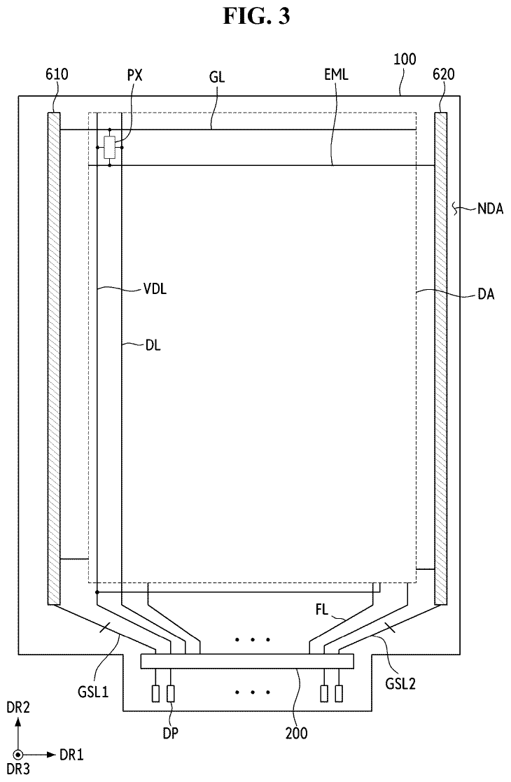

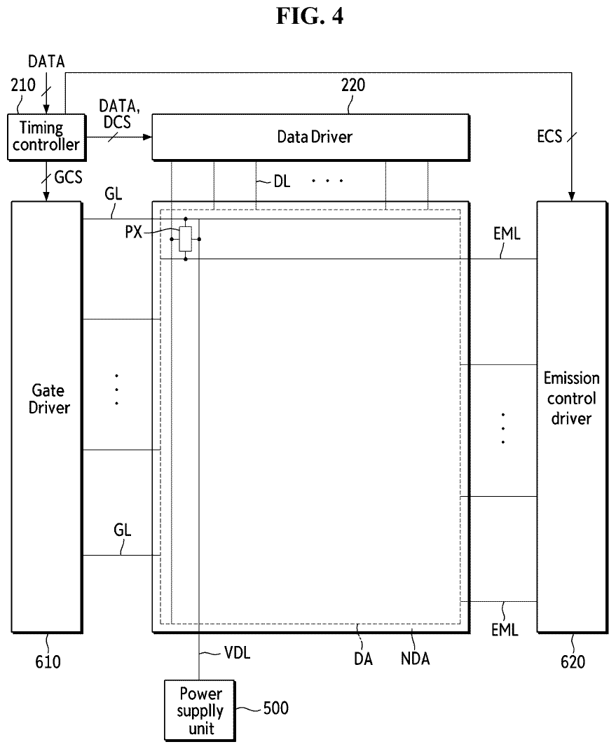

FIG. 3 is a plan view illustrating a display unit of the display device according to an embodiment, and FIG. 4 is a block diagram illustrating a display panel and a display driver according to an embodiment.

Referring to FIGS. 3 and 4, the display panel 100 may include a display area DA and a non-display area NDA.

The display area DA may include a plurality of pixels PX, a plurality of driving voltage lines VDL connected to the plurality of pixels PX, and a plurality of gate lines GL, a plurality of emission control lines EML, and a plurality of data lines DL of a plurality of common voltage lines.

Each of the plurality of pixels PX may be connected to the gate line GL, the data line DL, the emission control line EML, the driving voltage line VDL, and the common voltage line. Each of the plurality of pixels PX may include at least one transistor, a light emitting element, and a capacitor.

The gate lines GL may extend in the first direction DR1, and may be spaced apart from each other in the second direction DR2 crossing the first direction DR1. The gate lines GL may be arranged along the second direction DR2. The gate lines GL may sequentially supply gate signals to the plurality of pixels PX.

The emission control lines EML may extend in the first direction DR1, and may be spaced apart from each other in the second direction DR2. The emission control lines EML may be arranged along the second direction DR2. The emission control lines EML may sequentially supply emission signals to the plurality of pixels PX.

The data lines DL may extend in the second direction DR2, and may be spaced apart from each other in the first direction DR1. The data lines DTL may be arranged along the first direction DR1. The data lines DL may supply data voltages to the plurality of pixels PX. The data voltage may determine luminance of each of the plurality of pixels PX.

The driving voltage lines VDL may extend in the second direction DR2, and may be spaced apart from each other in the first direction DR1. The driving voltage lines VDL may be arranged along the first direction DR1. The driving voltage lines VDL may supply a first driving voltage to the plurality of pixels PX. The first driving voltage may be a high-potential voltage for driving the light emitting elements of the pixels PX.

The non-display areas NDA may surround the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltages received from the display driver 200 to the plurality of data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-area SBA may extend from one side of the non-display area NDA. The sub-area SBA may include the display driver 200 and pad portions DP. The pad portion DP may be located more adjacent to an edge of one side of the sub-area SBA than the display driver 200 is. The pad portion DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may control an operation timing of the data driver 220 by generating a data control signal DCS based on the timing signals, may control an operation timing of the gate driver 610 by generating the gate control signal GCS based on the timing signals, and may control an operation timing of the emission control driver 620 by generating the emission control signal ECS based on the timing signals. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. Gate signals of the gate driver 610 may select pixels PX to which the data voltages are supplied, and the selected pixels PX may receive the data voltages through the data lines DL.

The power supply unit 500 may be disposed on the circuit board 300 and may supply source voltages to the display driver 200 and the display panel 100. The power supply unit 500 may generate a driving voltage and supply the driving voltage to the driving voltage line VDL, may generate an initialization voltage and supply the initialization voltage to an initialization voltage line, and may generate a common voltage and supply the common voltage to a common electrode common to the light emitting elements of the plurality of pixels.

The gate driver 610 may be disposed outside one side of the display area DA or on one side of the non-display area NDA, and the emission control driver 620 may be disposed outside the other side of the display area DA or on the other side of the non-display area NDA, but embodiments of the present disclosure are not limited thereto. As another example, the gate driver 610 and the emission control driver 620 may be disposed on any one of one side and the other side of the non-display area NDA.

The gate driver 610 may include a plurality of transistors generating gate signals based on the gate control signal GCS. The emission control driver 620 may include a plurality of transistors generating emission signals based on the emission control signal ECS. For example, the transistors of the gate driver 610 and the transistors of the emission control driver 620 may be formed at a same layer as the transistors of each of the pixels PX. The gate driver 610 may supply the gate signals to the gate lines GL, and the emission control driver 620 may supply the emission signals to the emission control lines EML.

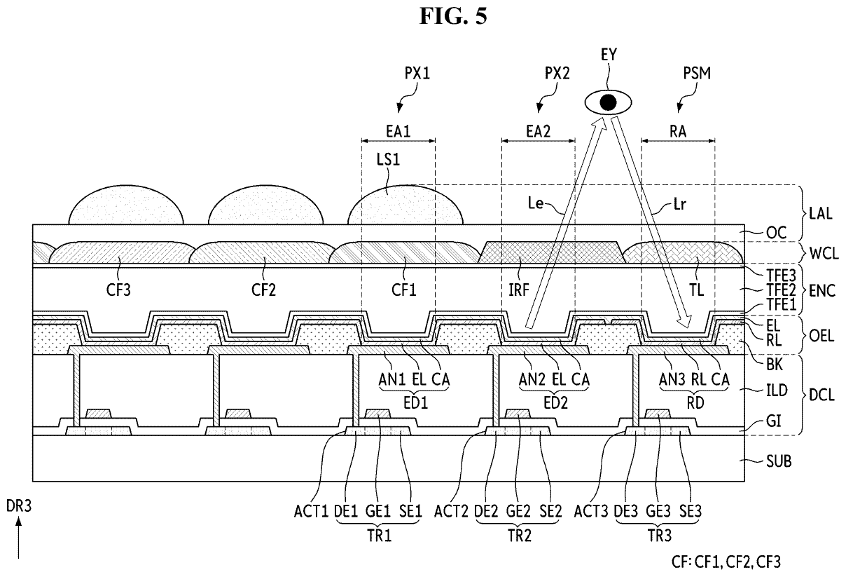

FIG. 5 is a cross-sectional view of the display device 10 according to an embodiment. For example, FIG. 5 may be a cross-sectional view of the display area DA of the display device 10 illustrated in FIG. 1.

The display device 10 according to an embodiment may include a substrate SUB, a driving circuit layer DCL, an optical element layer OEL, an encapsulation layer ENC, a wavelength conversion layer WCL, and a lens array layer LAL, as illustrated in FIG. 5.

The substrate SUB may be a base substrate or a base member. The substrate SUB may be a flexible substrate that may be bent, folded, and rolled. As an example, the substrate SUB may include a polymer resin such as, for example, polyimide (PI), but is not limited thereto. As another example, the substrate SUB may include a glass material or a metal material.

The driving circuit layer DCL may be disposed on the substrate SUB. The driving circuit layer DCL may include a plurality of transistors TR1, TR2, and TR3. For example, the driving circuit layer DCL may include a plurality of active layers ACT1, ACT2, and ACT3, a gate insulating layer GI, a plurality of gate electrodes GE1, GE2, and GE3, at least one interlayer insulating layer ILD, a first transistor TR1, a second transistor TR2, and a third transistor TR3. In some aspects, the driving circuit layer DCL may further include the gate lines GL, the data lines DL, the power lines, the gate control lines, the fan-out lines FL, and the lead lines connecting the display driver 200 and the pad portion to each other.

The gate insulating layer GI may be disposed on the substrate SUB. The gate insulating layer GI may include at least one of tetraethylorthosilicate (TEOS), silicon nitride (SiNₓ), and silicon oxide (SiO₂). As an example, the gate insulating layer GI may have a double-film structure in which a silicon nitride film and a tetraethoxysilane film are sequentially stacked.

The plurality of gate electrodes GE1, GE2, and GE3 may be disposed on the gate insulating layer GI. Each of the gate electrodes GE1, GE2, and GE3 may include at least one of molybdenum (Mo), copper (Cu), aluminum, and titanium (Ti), and may be formed as a single layer or multiple layers. For example, a first gate electrode GE1 may be formed as a triple film including a titanium film, an aluminum film, and a titanium film that are sequentially disposed along the third direction DR3 on the first gate insulating layer GI.

The interlayer insulating layer ILD may be disposed on the plurality of gate electrodes GE1, GE2, and GE3 and the gate insulating layer GI. The interlayer insulating layer ILD may include an inorganic film such as, for example, a silicon nitride layer, a silicon oxynitride layer, a silicon oxide layer, a titanium oxide layer, or an aluminum oxide layer. The display device 10 according to an embodiment may include a plurality of interlayer insulating layers ILD disposed between the gate insulating layer GI and the optical element layer OEL.

The first transistor TR1 may include the first gate electrode GE1, a first source electrode SE1, and a first drain electrode DE1. The first gate electrode GE1 may be disposed on the gate insulating layer GI and overlap a first active layer ACT1. Regions of the first active layer ACTI that do not overlap the first gate electrode GE1 may be the first source electrode SEI and the first drain electrode DE1, respectively.

The second transistor TR2 may include a second gate electrode GE2, a second source electrode SE2, and a second drain electrode DE2. The second gate electrode GE2 may be disposed on the gate insulating layer GI and overlap a second active layer ACT2. Regions of the second active layer ACT2 that do not overlap the second gate electrode GE2 may be the second source electrode SE2 and the second drain electrode DE2, respectively.

The third transistor TR3 may include a third gate electrode GE3, a third source electrode SE3, and a third drain electrode DE3. The third gate electrode GE3 may be disposed on the gate insulating layer GI and overlap a third active layer ACT3. Regions of the third active layer ACT3 that do not overlap the third gate electrode GE3 may be the third source electrode SE3 and the third drain electrode DE3, respectively.

The optical element layer OEL may be disposed on the driving circuit layer DCL. The optical element layer OEL may include a bank BK (or a pixel defining layer), a first light emitting element ED1, a second light emitting element ED2, and a light receiving element RD.

The first light emitting element EDI may include a first anode electrode AN1, a light emitting stack EL, and a cathode electrode CA. A first emission area EA1 may be an area where the first anode electrode AN1, the light emitting stack EL, and the cathode electrode CA are sequentially stacked and holes from the first anode electrode AN1 and electrons from the cathode electrode CA are combined with each other in the light emitting stack EL to emit light.

The second light emitting element ED2 may include a second anode electrode AN2, a light emitting stack EL, and a cathode electrode CA. A second emission area EA2 may be an area where the second anode electrode AN2, the light emitting stack EL, and the cathode electrode CA are sequentially stacked and holes from the second anode electrode AN2 and electrons from the cathode electrode CA are combined with each other in the light emitting stack EL to emit light.

The light receiving element RD may include a third anode electrode AN3, a light receiving layer RL, and a cathode electrode CA. The light receiving layer RL may receive light from the outside through a light receiving area RA. The light receiving layer RL may include a photoelectric conversion layer. The light receiving layer RL (e.g., the photoelectric conversion layer) may generate photocharges in proportion to incident light. The light incident on the light receiving layer RL may be light which is emitted from the light emitting stack EL (e.g., a light emitting stack EL of a second pixel PX2), reflected, and then enters the light receiving layer RL. Additionally, or alternatively, the light incident on the light receiving layer RL may be light provided from the outside regardless of the light emitting stack EL (e.g., the light emitting stack EL of the second pixel PX2). Charges generated and accumulated in the light receiving layer RL (e.g., the photoelectric conversion layer) may be converted into electrical signals for sensing.

In a top emission structure in which light is emitted toward the cathode electrode CA based on the light emitting stack EL, the anode electrode (e.g., AN1) may be formed as a single layer formed of molybdenum (Mo), titanium (Ti), copper (Cu), or aluminum (Al) or formed as a stacked structure (Ti/Al/Ti) of aluminum and titanium, a stacked structure (ITO/AI/ITO) of aluminum and indium tin oxide (ITO), an APC alloy, and a stacked structure (ITO/APC/ITO) of an APC alloy and ITO in order to increase reflectivity. The APC alloy is an alloy of silver (Ag), palladium (Pd), and copper (Cu).

The first anode electrode AN1, the second anode electrode AN2, and the third anode electrode AN3 may be disposed on the interlayer insulating layer ILD. The first anode electrode AN1 may be connected to the first drain electrode DEI through a contact hole penetrating through the interlayer insulating layer ILD and the gate insulating layer GI, the second anode electrode AN2 may be connected to the second drain electrode DE2 through a contact hole penetrating through the interlayer insulating layer ILD and the gate insulating layer GI, and the third anode electrode AN3 may be connected to the third drain electrode DE3 through a contact hole penetrating through the interlayer insulating layer ILD and the gate insulating layer GI.

The bank BK may define the emission areas EA1 and EA2 of the pixels PX1 and PX2 and the light receiving area RA of a light sensor module PSM. To this end, the bank BK may expose partial areas of the respective anode electrodes AN1, AN2, and AN3 on the interlayer insulating layer ILD. The bank BK may cover respective edges of the anode electrodes AN1, AN2, and AN3. Each of the emission areas EA1 and EA2 and the light receiving area RA may be a hole penetrating through the bank BK in the third direction DR3. The bank BK may be formed as an organic film formed of an acrylic resin, an epoxy resin, a phenolic resin, a polyamide resin, a polyimide resin, or the like.

The light emitting stack EL may be disposed on the bank BK, the first anode electrode AN1, and the second anode electrode AN2. The light emitting stack EL may include a plurality of stack layers. For example, the light emitting stack EL may have a three-tandem structure including a first stack layer, a second stack layer, and a third stack layer that are sequentially stacked along the third direction DR3. However, embodiments of the present disclosure are not limited thereto, and the light emitting stack EL may have, for example, a two-tandem structure including two stack layers.

In the three-tandem structure described herein, the light emitting stack EL may have a tandem structure including a plurality of stack layers that emit different light. For example, the light emitting stack EL may include a first stack layer emitting light of a first color, a second stack layer emitting light of a second color, and a third stack layer emitting light of a third color. The first stack layer, the second stack layer, and the third stack layer may be sequentially stacked along the third direction DR3.

The first stack layer may have a structure in which a first hole transporting layer, a first organic light emitting layer emitting the light of the first color, and a first electron transporting layer are sequentially stacked. The second stack layer may have a structure in which a second hole transporting layer, a second organic light emitting layer emitting the light of the second color, and a second electron transporting layer are sequentially stacked. The third stack layer may have a structure in which a third hole transporting layer, a third organic light emitting layer emitting the light of the third color, and a third electron transporting layer are sequentially stacked.

A first charge generation layer for supplying charges to the second stack layer and supplying electrons to the first stack layer may be disposed between the first stack layer and the second stack layer. The first charge generation layer may include an N-type charge generation layer supplying electrons to the first stack layer and a P-type charge generation layer supplying holes to the second stack layer. The N-type charge generation layer may include a dopant of a metal material.

A second charge generation layer for supplying charges to the third stack layer and supplying electrons to the second stack layer may be disposed between the second stack layer and the third stack layer. The second charge generation layer may include an N-type charge generation layer supplying electrons to the second stack layer and a P-type charge generation layer supplying holes to the third stack layer.

The first color, the second color, and the third color described herein may be different colors. For example, one of the first color, the second color, and the third color may be a red color, another of the first color, the second color, and the third color may be a green color, and the other of the first color, the second color, and the third color may be a blue color. The light emitting stack EL may provide light (e.g., white light) obtained by mixing the light of the first color from the first organic light emitting layer, the light of the second color from the second organic light emitting layer, and the light of the third color from the third organic light emitting layer with each other. Accordingly, each of the light emitting elements of the display device 10 including the first light emitting element EDI and the second light emitting element ED2 may provide the white light.

The light receiving layer RL may be disposed on the bank BK and the third anode electrode AN3. The light receiving layer RL (e.g., the photoelectric conversion layer) may include an electron donating material and an electron accepting material. The electron donating material may generate donor ions in response to light, and the electron accepting material may generate acceptor ions in response to light. In an example in which the light receiving layer RL (e.g., the photoelectric conversion layer) is formed of an organic material, the electron donating material may include a compound such as, for example, subphthalocyanine (SubPc) or dibutylphosphate (DBP), but is not limited thereto. The electron accepting material may include a compound such as, for example, fullerene, a fullerene derivative, or perylene diimide, but is not limited thereto.

When the light receiving layer RL (e.g., the photoelectric conversion layer) is formed of the organic material, a hole injecting layer (HIL) and a hole transporting layer (HTL) may be disposed at a lower portion of each light receiving layer RL (e.g., photoelectric conversion layer), and an electron injecting layer (EIL) and an electron transporting layer (ETL) may be stacked at an upper portion of each light receiving layer RL (e.g., photoelectric conversion layer). Each of these layers may be a single layer or multiple layers formed of an organic material.

Alternatively, when the light receiving layer RL (e.g., the photoelectric conversion layer) is formed of an inorganic material, the light receiving element RD may be a PN-type or PIN-type phototransistor. For example, the light receiving layer RL (e.g., the photoelectric conversion layer) may have a structure in which an N-type semiconductor layer, an I-type semiconductor layer, and a P-type semiconductor layer are sequentially stacked.

The light emitting stack EL may be further disposed on the light receiving layer RL. For example, the light emitting stack EL may further extend to the light receiving layer RL and be further disposed between the light receiving layer RL and the cathode electrode CA. In such a case, the light emitting stack EL and the light receiving layer RL may have a tandem structure together. In this case, the light emitting stack EL may be disposed at a higher level than the light receiving layer RL. For example, the light emitting stack EL of the light emitting stack EL and the light receiving layer RL may be located closer to the cathode electrode CA than the light receiving layer RL is.

The cathode electrode CA may be disposed on the light emitting stack EL and the light receiving layer RL. The cathode electrode CA may cover the light receiving stack EL and the light receiving layer RL. A capping layer may be further disposed on the cathode electrode CA.

In the top emission structure, the cathode electrode CA may be formed of a transparent conductive material (TCO) such as, for example, ITO or indium zinc oxide (IZO) capable of transmitting light or a semi-transmissive conductive material such as, for example, magnesium (Mg), silver (Ag), or an alloy of magnesium (Mg) and silver (Ag). In an example in which the cathode electrode CA is formed of the semi-transmissive conductive material, light emission efficiency may be increased by a micro cavity.

The encapsulation layer ENC may be formed on the optical element layer OEL. The encapsulation layer ENC may include at least one inorganic layer TFE1 or TFE3 in order to prevent oxygen or moisture from permeating into the optical element layer OEL. In some aspects, the encapsulation layer ENC may include at least one organic layer in order to protect the optical element layer OEL from foreign substances such as, for example, dust.

For example, the encapsulation layer ENC may include a first encapsulation inorganic layer TFE1, an encapsulation organic layer TFE2, and a second encapsulation inorganic layer TFE3.

The first encapsulation inorganic layer TFE1 may be disposed on the cathode electrode CA, the encapsulation organic layer TFE2 may be disposed on the first encapsulation inorganic layer TFE1, and the second encapsulation inorganic layer TFE3 may be disposed on the encapsulation organic layer TFE2. Each of the first encapsulation inorganic layer TFE1 and the second encapsulation inorganic layer TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic layer TFE2 may be an organic film formed of an acrylic resin, an epoxy resin, a phenolic resin, a polyamide resin, a polyimide resin, or the like.

The wavelength conversion layer WCL may be disposed on the encapsulation layer ENC. For example, the wavelength conversion layer WCL may be disposed between the encapsulation layer ENC (e.g., the second encapsulation inorganic layer TFE3) and the lens array layer LAL (e.g., an overcoat layer OC). The wavelength conversion layer WCL may include a plurality of color filters CF, an invisible light filter IRF, and a transparent layer TL. In some embodiments, the transparent layer TL may be omitted.

A first color filter CF1 may overlap the first emission area EA1 of a first pixel PX1 (e.g., a red pixel). The first color filter CF1 may transmit the light of the first color (e.g., light of a red wavelength band). Therefore, the first color filter CF1 may transmit the light of the first color among light emitted from the first emission area EA1.

A second color filter CF2 may overlap a first emission area of another first pixel (e.g., a green pixel). The second color filter CF2 may transmit the light of the second color (e.g., light of a green wavelength band). Therefore, the second color filter CF2 may transmit the light of the second color among light emitted from the first emission area of the corresponding pixel (e.g., the green pixel).

A third color filter CF3 may overlap a first emission area of still another first pixel (e.g., a blue pixel). The third color filter CF3 may transmit the light of the third color (e.g., light of a blue wavelength band). Therefore, the third color filter CF3 may transmit the light of the third color among light emitted from the first emission area of the corresponding pixel.

The invisible light filter IRF may overlap the second emission area EA2 of the second pixel PX2. The invisible light filter IRF may transmit invisible light (e.g., light of an infrared or near-infrared band). For example, the invisible light filter IRF may transmit infrared among white light from the second light emitting element ED2. The invisible light filter IRF may include a quantum dot, an organic pigment, or the like. The quantum dot may be formed of a material including InP, CdS, PbS, ZnS, CdSe, or the like, whose composition and size (e.g., diameter) are adjusted such that the quantum dot absorbs light of a visible light region and has an emission peak in an infrared region. For example, the diameter of the quantum dot may be greater than or equal to 2 nm and smaller than or equal to 10 nm. In some aspects, the quantum dot may include a core-shell-type quantum dot or a perovskite-type quantum dot.

The transparent layer TL (or a light transmitting layer) may overlap the light receiving area RA of the light sensor module PSM. The transparent layer TL may be formed of a material including a transparent resin. Light (e.g., infrared or near-infrared) incident on the transparent layer TL may be transmitted through the transparent layer TL.

The lens array layer LAL may be disposed on the wavelength conversion layer WCL. The lens array layer LAL may include an overcoat layer OC and a plurality of lenses LS1.

The overcoat layer OC may be disposed on the first color filter CF1, the second color filter CF2, the third color filter CF3, the invisible light filter IRF, and the transparent layer TL. A step between the color filters CF adjacent to each other, a step between the color filter CF and the invisible light filter IRF adjacent to each other, and a step between the invisible light filter IRF and the transparent layer TL adjacent to each other may be planarized by the overcoat layer OC.

The lenses LS1 may overlap the color filters CF, respectively. For example, the plurality of lenses LS1 may be disposed on the overcoat layer OC and overlap the first color filter CF1, the second color filter CF2, and the third color filter CF3, respectively. Each lens LS1 may have a parabolic shape convex along the third direction DR3. The overcoat layer OC and the plurality of lenses LS1 may be integrally formed with each other. For example, the overcoat layer OC and the plurality of lenses LS1 may be formed of the same material.

The display device 10 according to an embodiment as described herein may include the first pixel PX1, the second pixel PX2, and the light sensor module PSM, as illustrated in FIG. 5.

The first pixel PX1 may provide first light. The first light may be visible light. For example, the first light may be any one of red light, green light, and blue light. The number of first pixels PX1 may be plural. In such a case, the plurality of first pixels PX1 may be a red pixel providing the red light, a green pixel providing the green light, and a blue pixel providing the blue light, respectively. For example, the red pixel may provide red light (or red first light) as the first light, the green pixel may provide green light (or green first light) as the first light, and the blue pixel may provide blue light (or blue first light) as the first light. An image may be displayed by the first lights from the first pixels PX1.

The first pixel PX1 may include the first transistor TR1, the first light emitting element ED1, the color filter CF (e.g., CF1), and the lens LS1. The first light emitting element EDI may be connected to the first drain electrode DEI of the first transistor TR1. For example, the first anode electrode AN1 of the first light emitting element EDI may be connected to the first drain electrode DEI of the first transistor TR1 through at least one connection electrode disposed on a different layer.

The second pixel PX2 may provide second light (e.g., Le). The second light may be invisible light. For example, the second light may be infrared or near infrared. The second light Le emitted from the second pixel PX2 may be reflected from the outside and incident on the light sensor module PSM. For example, the second light Le from the second pixel PX2 may be incident on and then reflected from a user's eye EY (or retina), and the reflected light Lr may be incident on the light sensor module PSM.

The second pixel PX2 may include the second transistor TR2, the second light emitting element ED2, and the invisible light filter IRF. The second light emitting element ED2 may be connected to the second drain electrode DE2 of the second transistor TR2. For example, the second anode electrode AN2 of the second light emitting element ED2 may be connected to the second drain electrode DE2 of the second transistor TR2 through at least one connection electrode disposed on a different layer.

The light sensor module PSM may sense light from the outside. For example, the light sensor module PSM may sense the second light Le. As a specific example, the light sensor module PSM may sense the second light Lr (e.g., the infrared or the near-infrared) emitted from the second pixel PX2 and then reflected by the user's eye.

The light sensor module PSM may include the third transistor TR3, the light receiving element RD, and the transparent layer TL. The light receiving element RD may be connected to the third drain electrode DE3 of the third transistor TR3. For example, the third anode electrode AN3 of the light receiving element RD may be connected to the third drain electrode DE3 of the third transistor TR3 through at least one connection electrode disposed on a different layer.

The display device 10 according to an embodiment may sense an external object through the second pixel PX2 and the light sensor module PSM. In some aspects, the display device 10 according to an embodiment may sense a location of the user's eye EY (or retina) through the second pixel PX2 and the light sensor module PSM, and accordingly, track a user's sight line. The display device may decide a degree to which the user's eye perceives the movement of an image based on a user's sight line moving direction or the like. In some aspects, the display device corrects image data based on this decision, such that a problem such as, for example, a dizziness phenomenon that may occur when a user views the display device (particularly, a head mounted display (HMD)) may be solved.

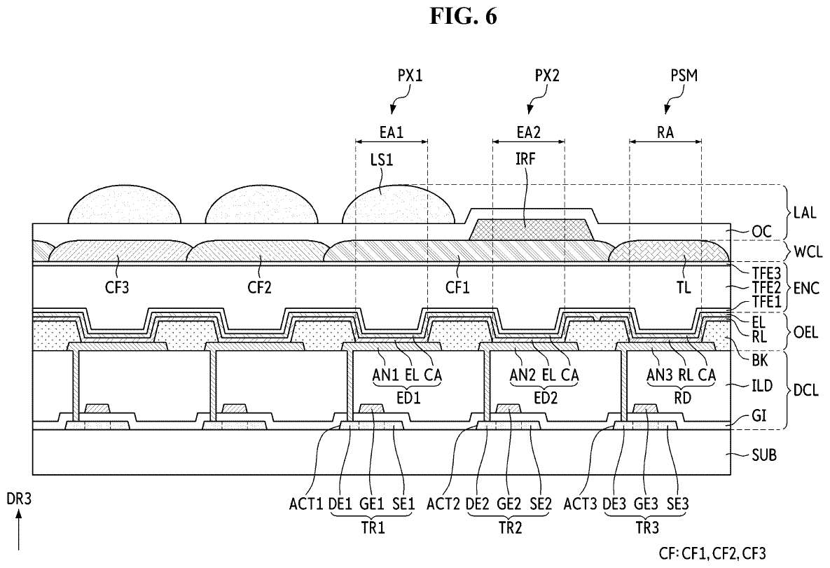

FIG. 6 is a cross-sectional view of a display device according to another embodiment. For example, FIG. 6 may be a cross-sectional view of the display area DA of the display device 10 illustrated in FIG. 1.

The display device 10 of FIG. 6 is different from the display device 10 described herein with reference to FIG. 5 in locations of the color filters CF and the invisible light filter IRF, and such a difference will be mainly described herein.

As illustrated in FIG. 6, the second pixel PX2 may further include a first color filter CF1. The first color filter CF1 of the second pixel PX2 may overlap the second emission area EA2 of the second pixel PX2. In this case, the first color filter CF1 of the second pixel PX2 may be integrally formed with the first color filter CF1 of the first pixel PX1 adjacent to the second pixel PX2. For example, the first color filter CF1 may be commonly included in the first pixel PX1 and the second pixel PX2 adjacent to each other. In other words, the first color filter CFI may overlap the first emission area EA1 and the second emission area EA2. Accordingly, the first color filter CFI may have a greater size than other color filters. For example, in a plan view, an area of the first color filter CF1 in the first direction DR1 and the second direction DR2 may be greater than an area of the second color filter CF2 (or the third color filter CF3) in the first direction DR1 and the second direction DR2. The first color filter CF1 may be a red color filter capable of selectively transmitting the red light.

The invisible light filter IRF of the second pixel PX2 may be disposed on the first color filter CF1. For example, the invisible light filter IRF may be disposed on the first color filter CF1 and overlap the second emission area EA2. In other words, the invisible light filter IRF may be disposed between the first color filter CFI and the overcoat layer OC. Accordingly, a height of the overcoat layer OC may be greater in an area that overlaps the invisible light filter IRF than in an area that does not overlap the invisible light filter IRF. Here, the height may be defined as a distance from an interface between the color filter CF and the encapsulation layer ENC (e.g., the second encapsulation inorganic layer TFE3) to an upper surface of the overcoat layer OC in the third direction DR3. The invisible light filter IRF may selectively transmit infrared among the first light (e.g., the red light) from the first color filter CF1.

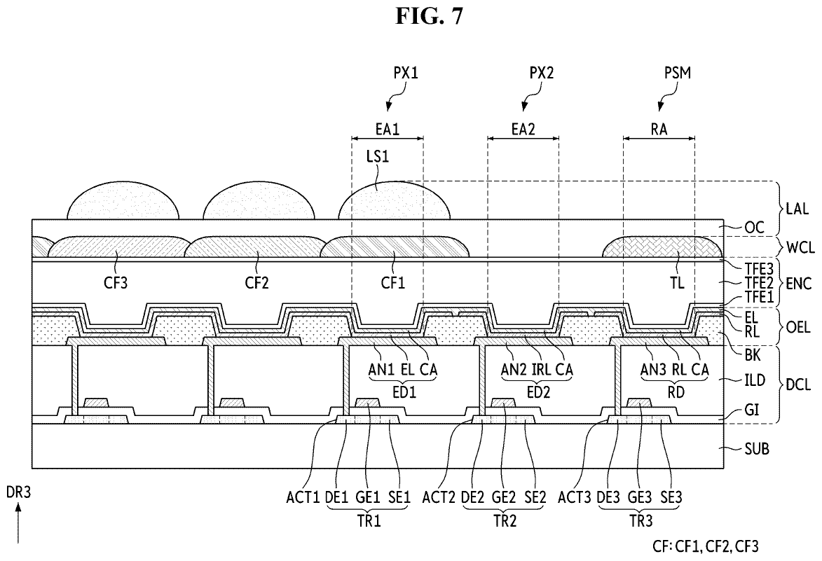

FIG. 7 is a cross-sectional view of a display device 10 according to another embodiment. For example, FIG. 7 may be a cross-sectional view of the display area DA of the display device 10 illustrated in FIG. 1.

The display device 10 of FIG. 7 is different from the display device described herein with reference to FIG. 5 in that the display device 10 of FIG. 7 includes an invisible light emitting layer IRL capable of providing invisible light (e.g., ultraviolet or near ultraviolet) instead of the invisible light filter IRF, and such a difference will be mainly described herein.

The display device according to another embodiment may include the invisible light emitting layer IRL, as illustrated in FIG. 7. For example, the second pixel PX2 may include the invisible light emitting layer IRL instead of the light emitting stack EL. In other words, the second pixel PX2 may include the second transistor TR2 and the second light emitting element ED2 emitting second light Le, which is invisible light, and the second light emitting element ED2 may include the invisible light emitting layer IRL. Here, the second light emitting element ED2 may include the second anode electrode AN2, the invisible light emitting layer IRL disposed on the second anode electrode AN2, and the cathode electrode CA disposed on the invisible light emitting layer IRL.

The invisible light emitting layer IRL may be, for example, a light emitting layer capable of emitting infrared or near-infrared. The invisible light emitting layer IRL may include a material capable of emitting infrared or near-infrared. The light from the invisible light emitting layer IRL may be reflected from the outside and then incident on the light sensor module PSM.

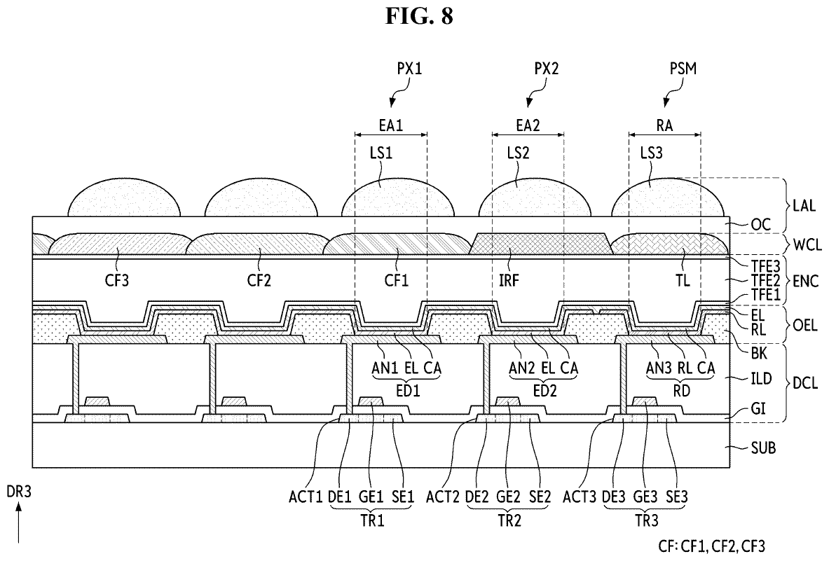

FIG. 8 is a cross-sectional view of a display device 10 according to another embodiment. For example, FIG. 8 may be a cross-sectional view of the display area DA of the display device 10 illustrated in FIG. 1.

The display device 10 of FIG. 8 is different from the display device described herein with reference to FIG. 5 in that at least one of the second pixel PX2 and the light sensor module PSM further includes a lens LS2 or LS3, and such a difference will be mainly described herein.

As illustrated in FIG. 8, the second pixel PX2 may further include a lens LS2 which is disposed on the overcoat layer OC and overlaps the invisible light filter IRF (or the second emission area EA2), and the light sensor module PSM may further include a lens LS3 which is disposed on the overcoat layer OC and overlaps the transparent layer TL (or the light receiving area RA).

At least one of the second pixel PX2 and the light sensor module PSM of the display device 10 of FIG. 6 may further include a lens LS2 or LS3, and at least one of the second pixel PX2 and the light sensor module PSM of the display device 10 of FIG. 7 may further include a lens LS2 or LS3.

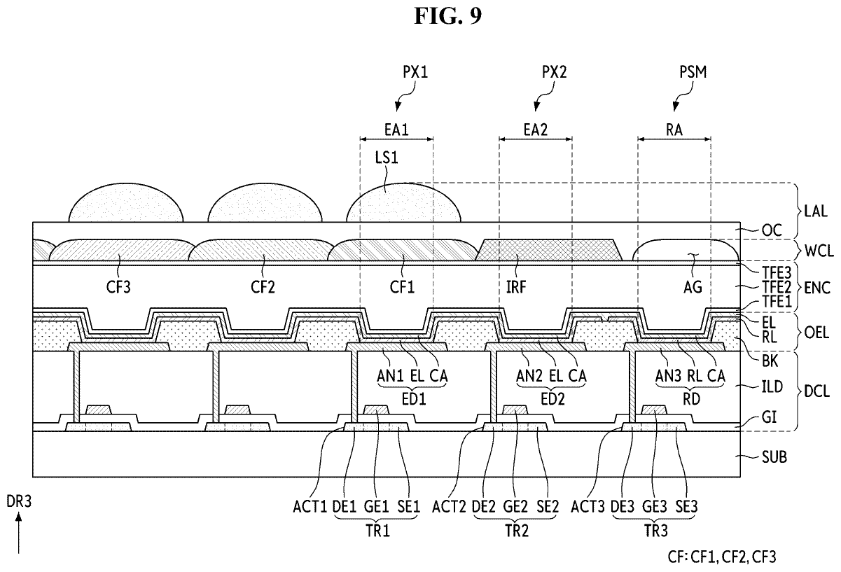

FIG. 9 is a cross-sectional view of a display device 10 according to another embodiment. For example, FIG. 9 may be a cross-sectional view of the display area DA of the display device 10 illustrated in FIG. 1.

The display device 10 of FIG. 9 is different from the display device 10 described herein with reference to FIG. 5 in that the light sensor module PSM includes an air gap AG instead of the transparent layer TL, and such a difference will be mainly described herein.

As illustrated in FIG. 9, the light sensor module PSM may include the air gap AG, and the air gap AG may be disposed on the encapsulation layer ENC (e.g., the second encapsulation inorganic layer TFE3) and overlap the light receiving area RA. For example, the air gap AG may be disposed between the encapsulation layer ENC (e.g., the second encapsulation inorganic layer TFE3) and the overcoat layer OC.

The light sensor module PSM of the display device 10 of FIG. 6 may include an air gap AG instead of the transparent layer TL, and the light sensor module PSM of the display device of FIG. 7 may include an air gap AG instead of the transparent layer TL.

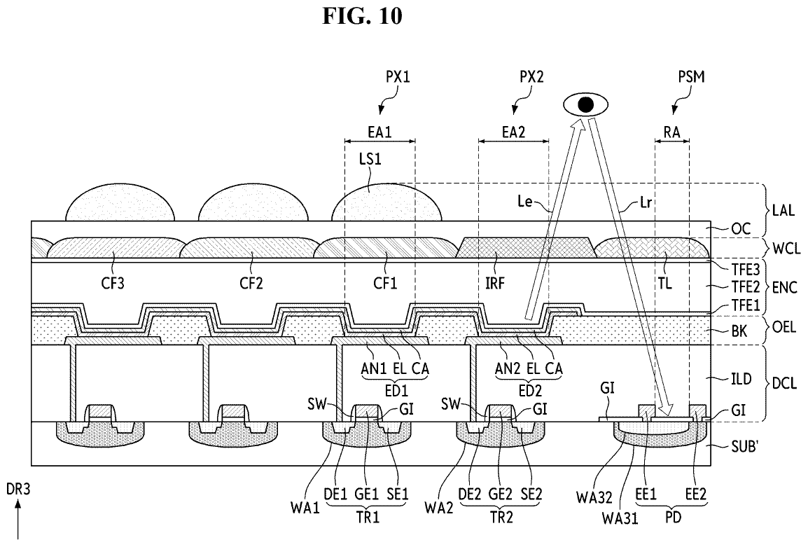

FIG. 10 is a cross-sectional view of a display device 10 according to another embodiment. For example, FIG. 10 may be a cross-sectional view of the display area DA of the display device 10 illustrated in FIG. 1.

The display device 10 of FIG. 10 is different from the display device 10 described herein with reference to FIG. 5 in the substrate SUB, the first transistor TR1, the second transistor TR2, and the light receiving element RD, and such a difference will be mainly described herein.

The substrate SUB in FIG. 10 may be a wafer substrate SUB′ (or a semiconductor substrate). For example, the substrate SUB′ of FIG. 10 may be a silicon substrate, a germanium substrate, or a silicon-germanium substrate. The substrate SUB′ may be a substrate doped with first-type impurities.

A first well region WA1, a second well region WA2, a third-first well region WA31, and a third-second well region WA32 may be disposed in the substrate SUB′. Each of the first well region WA1, the second well region WA2, and the third-first well region WA31 may be doped with second-type impurities. For example, the substrate SUB′ may be doped with p-type impurities, and each of the first well region WA1, the second well region WA2, and the third-first well region WA31 may be doped with n-type impurities.

As illustrated in FIG. 10, each of the first transistor TR1 of the first pixel PX1 and the second transistor TR2 of the second pixel PX2 may be a metal oxide semiconductor field effect transistor (MOSFET).

The first transistor TR1 may include a first gate electrode GE1, a first source electrode SE1 (or a first source region), and a first drain electrode DE1 (or a first drain region). The first gate electrode GE1 may be disposed on the gate insulating layer GI and overlap the first well region WA1. The first source electrode SE1 and the first drain electrode DE1 may be disposed in the first well region WA1. In a plan view, the first gate electrode GE1 may be disposed between the first source electrode SE1 and the first drain electrode DE1 in the first well region WA1. Sidewalls SW may be disposed on opposite sides of the first gate electrode GE1.

The second transistor TR2 may include a second gate electrode GE2, a second source electrode SE2 (or a second source region), and a second drain electrode DE2 (or a second drain region). The second gate electrode GE2 may be disposed on the gate insulating layer GI and overlap the second well region WA2. The second source electrode SE2 and the second drain electrode DE2 may be disposed in the second well region WA2. In a plan view, the second gate electrode GE2 may be disposed between the second source electrode SE2 and the second drain electrode DE2 in the second well region WA2. Sidewalls SW may be disposed on opposite sides of the second gate electrode GE2.

As illustrated in FIG. 10, the light sensor module PSM may include a light receiving element RD and a transparent layer TL.

The light receiving element RD may be disposed between the substrate SUB′ and the transparent layer TL. As illustrated in FIG. 10, the light receiving element RD may be a photodiode. Such a light receiving element RD may include a first electrode EE1 and a second electrode EE2. The first electrode EE1 of the light receiving element RD may be an anode electrode, and the second electrode EE2 of the light receiving element RD may be a cathode electrode CA. The first electrode EE1 of the light receiving element RD may be disposed on the third-second well region WA32. The third-second well region WA32 may be disposed in the third-first well region WA31. The second electrode EE2 of the light receiving element RD may be disposed on the third-first well region WA31. Each of the third-second well region WA32, the first source electrode SE1 (or the first source region), the first drain electrode DE1 (or the first drain region), the second source electrode SE2 (or the second source region), and the second drain electrode DE2 (or the second drain region) may be doped with first-type impurities. The first electrode EE1 may be in contact with the third-second well region WA32 through a contact hole penetrating through the gate insulating layer GI on the gate insulating layer GI, and the second electrode EE2 may be in contact with the third-first well region WA31 through a contact hole penetrating through the gate insulating layer GI on the gate insulating layer GI. Light from the outside (e.g., second light Lr emitted from the second pixel PX2 and reflected) may be incident on the third-second well region WA32 of the light receiving element RD. In this case, the light receiving area RA of the light receiving element RD may be located between the first electrode EE1 and the second electrode EE1. The gate insulating layer GI disposed on the third-first well region WA31 and the third-second well region WA32 may be an anti-reflection layer.

The transparent layer TL may be disposed on the encapsulation layer ENC (e.g., the second encapsulation inorganic layer TFE3) and overlap the light receiving element RD. Insulating layers may be disposed between the transparent layer TL and the light receiving element RD. For example, non-metallic layers (e.g., the interlayer insulating layer ILD, the bank BK, and the encapsulation layer ENC) may be disposed between the transparent layer TL and the light receiving element RD. In other words, a metal layer may not be disposed between the transparent layer TL and the light receiving element RD. Accordingly, the light from the outside (e.g., the second light Le) may be more easily incident on the light receiving element RD through the transparent layer TL.

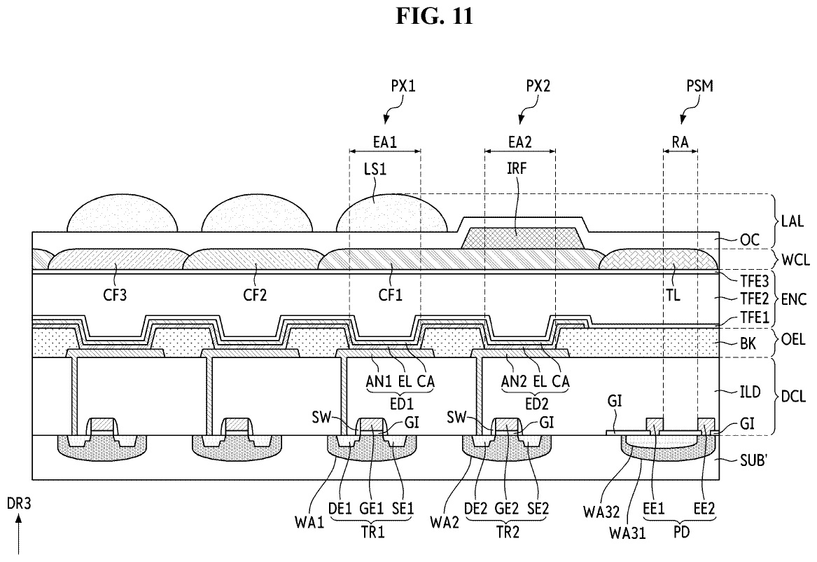

FIG. 11 is a cross-sectional view of a display device 10 according to another embodiment. For example, FIG. 11 may be a cross-sectional view of the display area DA of the display device 10 illustrated in FIG. 1.

The display device 10 of FIG. 11 is different from the display device described herein with reference to FIG. 10 in locations of the color filters CF and the invisible light filter IRF, and such a difference will be mainly described herein.

Here, in relation to the locations of the color filters CF and the invisible light filter IRF of FIG. 11, reference is made to FIG. 6 and the related description.

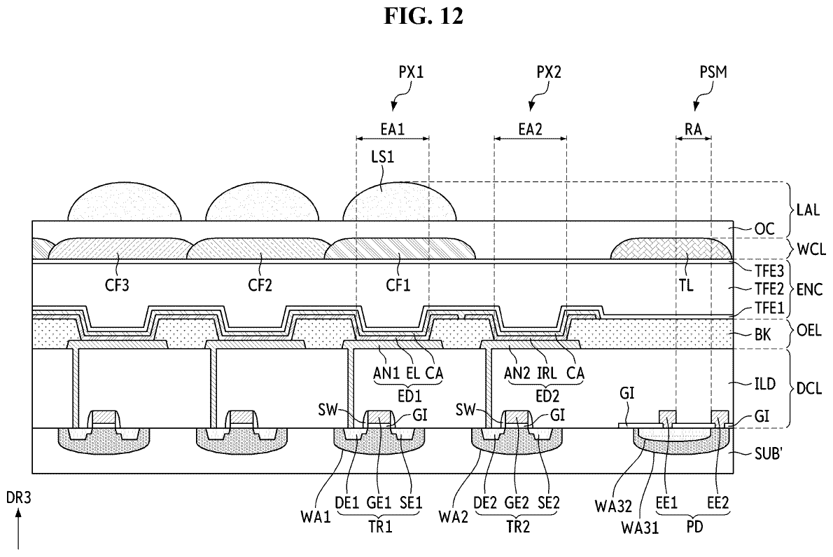

FIG. 12 is a cross-sectional view of a display device 10 according to another embodiment. For example, FIG. 12 may be a cross-sectional view of the display area DA of the display device 10 illustrated in FIG. 1.

The display device 10 of FIG. 12 is different from the display device described herein with reference to FIG. 10 in that the display device 10 of FIG. 12 includes an invisible light emitting layer IRL capable of providing invisible light instead of the invisible light filter IRF, and such a difference will be mainly described herein.

Here, in relation to the invisible light emitting layer IRL, reference is made to FIG. 7 and the related description.

The first pixels PX1 may be disposed in the display area DA of the display panel 100, whereas the second pixels PX2 and the light sensor modules PSM may be disposed in the non-display area NDA of the display panel 100. In such a case, an area occupied by the second pixels PX2 and the light sensor modules PSM in the display area DA may be filled with the first pixels PX1, and thus, the display device 10 capable of sensing an external object without a decrease in resolution may be implemented.

The display device 10 according to an embodiment may be applied to various electronic devices. An electronic device according to an embodiment includes the display device 10 described herein, and may further include modules or devices having other additional functions in addition to the display device 10.

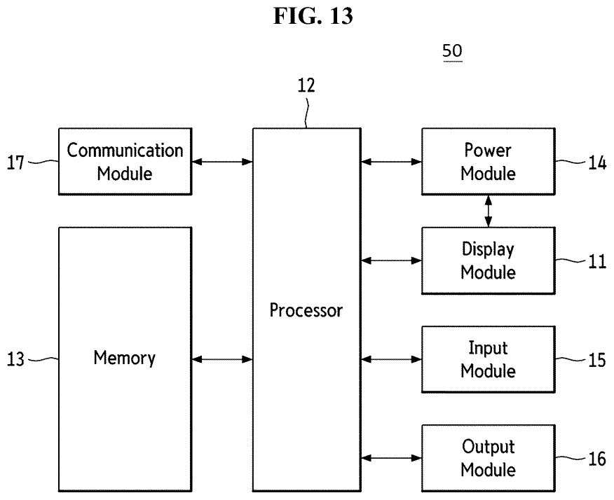

FIG. 13 is a block diagram of an electronic device according to an embodiment. Referring to FIG. 13, an electronic device 50 according to an embodiment may include a display module 11, a processor 12, a memory 13, and a power module 14. The electronic device 50 may further include an input module 15, a non-image output module 16, and/or a communication module 17.

The electronic device 50 may output various information in the form of an image through the display module 11. In an example in which the processor 12 executes an application stored in the memory 13, image information provided by the application may be provided to a user through the display module 11. The power module 14 may include a power supply module such as, for example, a power adapter or a battery device and a power conversion module converting power supplied by the power supply module to generate power supportive of an operation of the electronic device 50. The input module 15 may provide input information to the processor 12 and/or the display module 11. The non-image output module 16 may serve to receive information other than an image received from the processor 12, such as, for example, sound information, haptic information, and light emitting information, and provide the received information to the user. The communication module 17 is a module in charge of transmitting and receiving information between the electronic device 50 and an external device, and may include a receiving unit and a transmitting unit.

At least one of the respective components of the electronic device 50 described herein may be included in the display device according to the embodiments described herein. In some aspects, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device 50 rather than the display device.

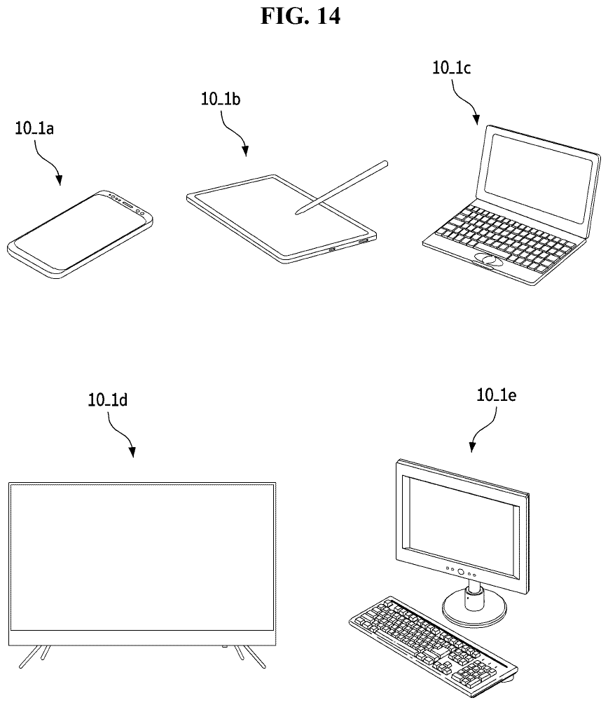

FIGS. 14 to 16 are schematic views of electronic devices according to various embodiments. FIGS. 14 to 16 illustrate examples of various electronic devices to which a display device 10 according to embodiments is applied.

FIG. 14 illustrates a smartphone 10_1a, a tablet personal computer (PC) 10_1b, a laptop computer 10_1c, a television (TV) 10_1d, and a monitor 10_1e for a desktop computer as examples of the electronic devices.

The smartphone 10_1a may include an input module such as, for example, a touch sensor and a communication module in addition to the display module 11. The smartphone 10_1a may process information received through the communication module or other input modules and display the processed information through the display module of the display device.

Each of the tablet PC 10_1b, the laptop computer 10_1c, the TV 10_1d, and the monitor 10_1e for a desktop computer may include a display module and an input module, similar to the smartphone 10_1a, and may further include a communication module in some cases.

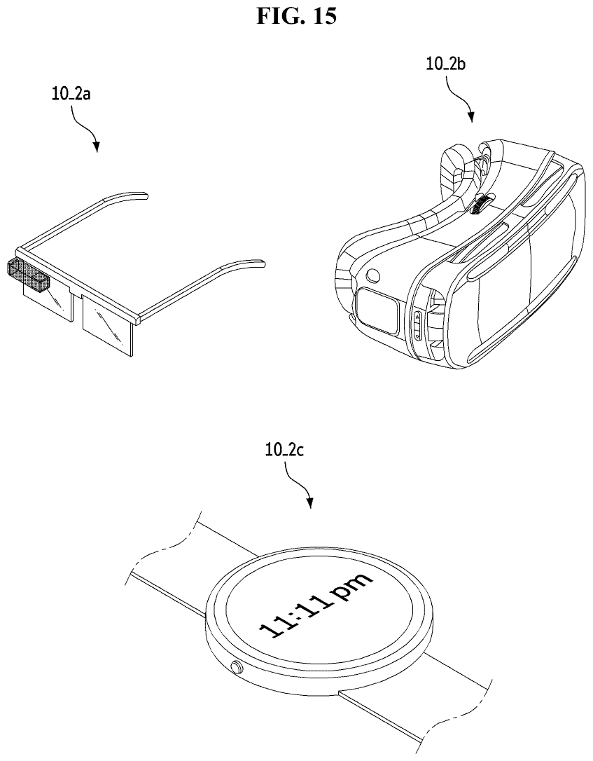

FIG. 15 illustrates a case where an electronic device including a display module is applied to a wearable electronic device. The wearable electronic device may be a smart glasses 10_2a, a head mounted display 10_2b, a smart watch 10_2c, or the like.

The smart glasses 10_2a and the head mounted display 10_2b may include a display module emitting a display image and a reflector reflecting the emitted display image and providing the emitted display image to user's eyes, and accordingly, may provide a virtual reality screen or an augmented reality screen to the user.

The smart watch 10_2c may include a biometric sensor as an input device, and may provide biometric information recognized through the biometric sensor to the user through the display module.

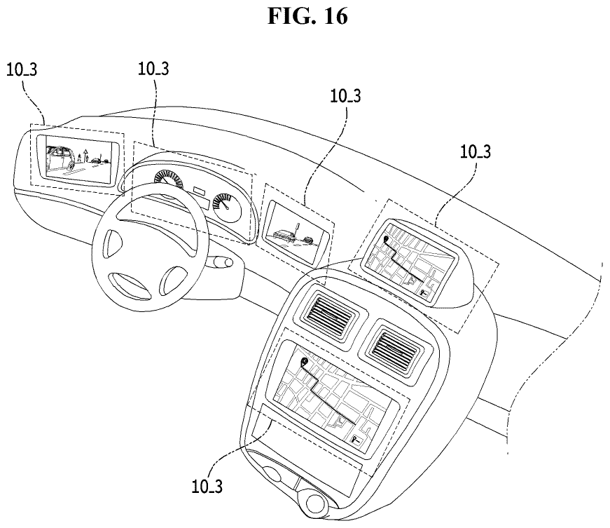

FIG. 16 illustrates a case where an electronic device including a display module is applied to a vehicle. For example, an electronic device 10_3 may be applied to an instrument board, a center fascia, or the like, of the vehicle or applied to a center information display (CID) disposed on a dashboard of the vehicle, a room mirror display substituting for a side-view mirror, or the like.

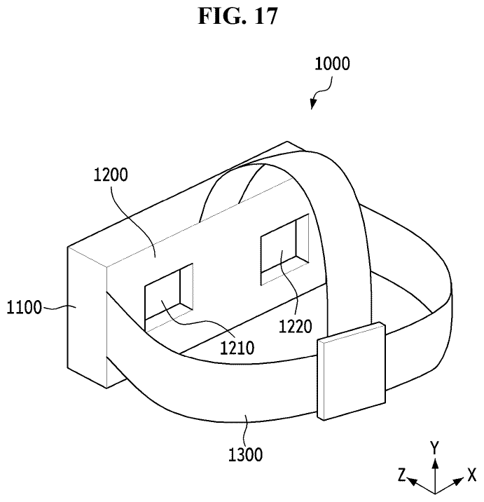

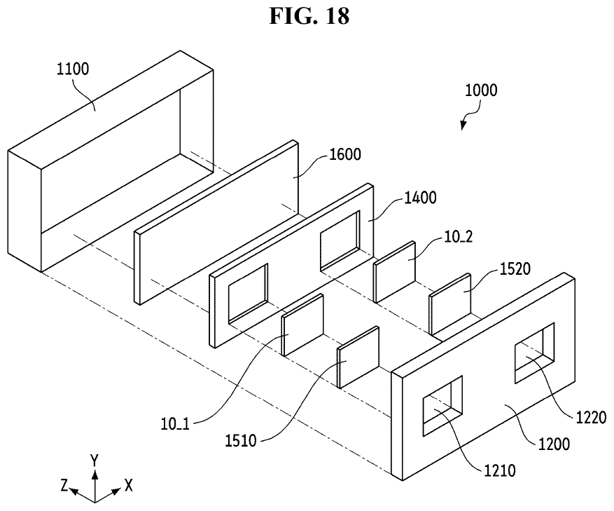

FIG. 17 is a perspective view illustrating a head mounted display device according to an embodiment. FIG. 18 is an exploded perspective view illustrating an example of the head mounted display device of FIG. 17.

Referring to FIGS. 17 and 18, a head mounted display device 1000 according to an embodiment includes a first display device 10_1, a second display device 10_2, a display device housing portion 1100, a housing portion cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIGS. 1 to 12, and a description of the first display device 10_1 and the second display device 10_2 is thus omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing portion 1100. The control circuit board 1600 may be connected to the first display device 10_1 and the second display device 10_2 through a connector. The control circuit board 1600 may convert an image source input from the outside into digital video data DATA, and transmit the digital video data DATA to the first display device 10_1 and the second display device 10_2 through the connector.

The control circuit board 1600 may transmit digital video data DATA corresponding to a left eye image optimized for the user's left eye to the first display device 10_1 and transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device housing portion 1100 serves to house the first display device 10_1, the second display device 10_2, the middle frame 1400, the first optical member 1510, the second optical member 1520, and the control circuit board 1600. The housing portion cover 1200 covers opened one surface of the display device housing portion 1100. The housing portion cover 1200 may include the first eyepiece 1210 on which the user's left eye is disposed and the second eyepiece 1220 on which the user's right eye is disposed. It has been illustrated in FIGS. 17 and 18 that the first eyepiece 1210 and the second eyepiece 1220 are separately disposed, but an embodiment of embodiments of the present disclosure are not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

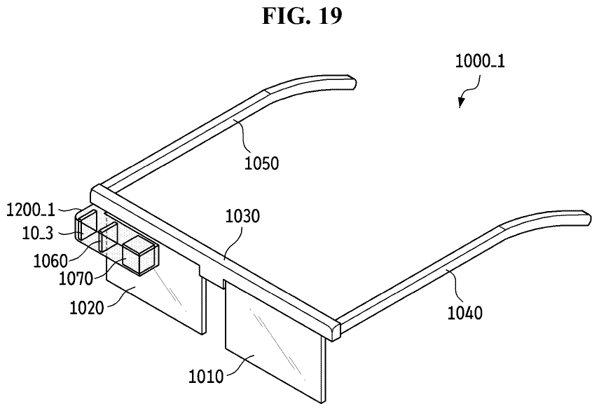

The head mounted band 1300 serves to fix the display device housing portion 1100 to a user's head such that the first eyepiece 1210 and the second eyepiece 1220 of the housing portion cover 1200 may be maintained in a state where they are disposed on the user's left eye and right eye, respectively. In an example in which the display device housing portion 1100 is implemented to have a light weight and a small size, the head mounted display device 1000 may include an eyeglass frame as illustrated in FIG. 19 instead of the head mounted band 1300.

In some aspects, the head mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 19 is a perspective view illustrating a head mounted display device according to another embodiment.

Referring to FIG. 19, a head mounted display device 1000_1 according to another embodiment may be a glasses-type display device in which a display device housing portion 1200_1 is implemented to have a light weight and a small size. The head mounted display device 1000_1 according to another embodiment may include a display device 10_3, a left eye lens 1010, a right eye lens 1020, a support frame 1030, glasses frame legs 1040 and 1050, an optical member 1060, an optical path conversion member 1070, and a display device housing portion 1200_1.

The display device housing portion 1200_1 may include the display device 10_3, the optical member 1060, and the optical path conversion member 1070. An image displayed on the display device 10_3 may be magnified by the optical member 1060, converted in an optical path by the optical path conversion member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 19 that the display device housing portion 1200_1 is disposed at a right end of the support frame 1030, but embodiments of the present disclosure are not limited thereto. For example, the display device housing portion 1200_1 may be disposed at a left end of the support frame 1030, and in this case, an image of the display device 10_3 may be provided to a user's left eye. Alternatively, the display device housing portions 1200_1 may be disposed at both the left and right ends of the support frame 1030, and in this case, the user may view an image displayed on the display device 10_3 through both his/her left and right eyes.

In concluding the detailed description, those skilled in the art will appreciate that

many variations and modifications can be made to the example embodiments without substantially departing from the principles of the present invention. Therefore, the disclosed example embodiments of the present disclosure are used in a generic and descriptive sense and not for purposes of limitation.

What is claimed is:

1. A display device comprising:
a substrate; and
a first pixel, a second pixel, and a light sensor module disposed on the substrate,
wherein:
the first pixel comprises a first light emitting element and a first color filter disposed on the first light emitting element, and
the second pixel comprises a second light emitting element, a second color filter disposed on the second light emitting element, and an invisible light filter disposed on the second color filter.

2. The display device of claim 1, wherein the first color filter and the second color filter are integrally formed with each other.

3. The display device of claim 2, wherein in a plan view, a size of a color filter comprising the first color filter and the second color filter is greater than respective sizes of color filters of other pixels.

4. The display device of claim 1, wherein each of the first color filter and the second color filter selectively transmits red light.

5. The display device of claim 1, wherein:
each of the first light emitting element and the second light emitting element provides visible light, and
the invisible light filter selectively transmits infrared light or near-infrared light among the visible light provided from the second light emitting element.

6. The display device of claim 1, wherein the light sensor module receives light which is emitted from the second pixel and then provided from outside the display device.

7. The display device of claim 1, wherein:
the first pixel provides first light comprising visible light, and
the second pixel provides second light comprising invisible light.

8. The display device of claim 1, further comprising an overcoat layer disposed on the first color filter, the second color filter, and the invisible light filter.

9. The display device of claim 8, wherein a height of the overcoat layer is greater in an area that overlaps the invisible light filter than in an area that does not overlap the invisible light filter.

10. The display device of claim 1, wherein:
the first pixel is disposed in a display area of the substrate, and
the second pixel and the light sensor module are disposed in a non-display area of the substrate.

11. The display device of claim 1, wherein the substrate is a glass substrate or a wafer substrate.

12. An optical device comprising:
a display device; and
an optical path conversion member disposed on the display device,
wherein:
the display device comprises:
a substrate; and
a first pixel, a second pixel, and a light sensor module disposed on the substrate,
the first pixel comprises a first light emitting element and a first color filter disposed on the first light emitting element, and
the second pixel comprises a second light emitting element, a second color filter disposed on the second light emitting element, and an invisible light filter disposed on the second color filter.

13. The optical device of claim 12, wherein the first color filter and the second color filter are integrally formed with each other.

14. The optical device of claim 13, wherein in a plan view, a size of a color filter comprising the first color filter and the second color filter is greater than respective sizes of color filters of other pixels.

15. The optical device of claim 12, wherein each of the first color filter and the second color filter selectively transmits red light.

16. The optical device of claim 12, wherein:
each of the first light emitting element and the second light emitting element provides visible light, and
the invisible light filter selectively transmits infrared light or near-infrared light among the visible light provided from the second light emitting element.

17. The optical device of claim 12, wherein the light sensor module receives light which is emitted from the second pixel and then provided from outside the display device.

18. The optical device of claim 12, wherein:
the first pixel provides first light comprising visible light, and
the second pixel provides second light comprising invisible light.

19. The optical device of claim 12, wherein the display device further comprises an overcoat layer disposed on the first color filter, the second color filter, and the invisible light filter,
wherein a height of the overcoat layer is greater in an area that overlaps the invisible light filter than in an area that does not overlap the invisible light filter.

20. An electronic device comprising a display device providing a screen,
wherein:
the display device comprises:
a substrate; and
a first pixel, a second pixel, and a light sensor module disposed on the substrate,
the first pixel comprises a first light emitting element and a first color filter disposed on the first light emitting element, and
the second pixel comprises a second light emitting element, a second color filter disposed on the second light emitting element, and an invisible light filter disposed on the second color filter.
